(19) United States
(12) Patent Application Publication
(10) Pub. No.: US 2026/0156899 A1
(43) Pub. Date: Jun. 4, 2026

(54) SEMICONDUCTOR DEVICE

(71) Applicant: DENSO CORPORATION, Kariya-city (JP)

(72) Inventors: Shin TAKIZAWA, Kariya-city (JP); Yusuke NONAKA, Kariya-city (JP); Kenta GODA, Kariya-city (JP); Takeshi HAGINO, Kariya-city (JP)

(21) Appl. No.: 19/421,644

(22) Filed: Dec. 16, 2025

Related U.S. Application Data
(63) Continuation of application No. PCT/JP2024/023782, filed on Jul. 1, 2024.

(30) Foreign Application Priority Data
Jul. 7, 2023 (JP) 2023-112386

(51) Int. Cl. H10D 64/27; H10D 12/00; H10D 30/60

(52) U.S. Cl. CPC H10D 64/513; H10D 12/416; H10D 30/611

(57) ABSTRACT

A semiconductor device includes a semiconductor switching element having a double-gate trench gate structure. The semiconductor switching element includes an upper electrode electrically connected to a body region of a second conductivity type and an impurity region of a first conductivity type, a gate wiring connected to a gate electrode layer of the double-gate trench gate structure, and a shield wiring connected to a shield electrode of the double-gate trench gate structure. The upper electrode, the gate wiring and the shield wiring are electrically isolated from each other.

### CROSS REFERENCE TO RELATED APPLICATIONS

The present application is a continuation application of International Patent Application No. PCT/JP2024/023782 filed on Jul. 1, 2024, which designated the U.S. and claims the benefit of priority from Japanese Patent Application No. 2023-112386 filed on Jul. 7, 2023. The entire disclosures of all of the above applications are incorporated herein by reference.

### TECHNICAL FIELD

The present disclosure relates to a semiconductor device including a semiconductor switching element having a double-gate trench gate structure.

### BACKGROUND

For example, a semiconductor device including a power MOSFET having a double-gate trench gate structure has been known. In the semiconductor device, the double-gate trench gate structure is formed in a surface layer of a semiconductor substrate in which an n⁻ type drift layer is formed on an n⁺ type substrate. In the double-gate trench gate structure, a shield electrode, which is set to a source potential, is disposed at a bottom side of the gate trench via a shield insulation film. Further, a gate electrode layer is disposed above the shield electrode through a gate insulation film in the trench, thereby forming a double gate. An interlayer insulation film, in other words, an intermediate insulation film is formed between the shield electrode and the gate electrode layer. Thus, the intermediate insulation film insulates the shield electrode and the gate electrode layer from each other.

### SUMMARY

The present disclosure describes a semiconductor device including a semiconductor switching element having a double-gate trench gate structure. According to an aspect of the present disclosure, the semiconductor switching element of the semiconductor device includes: a drift layer of a first conductivity type; a body region of a second conductivity type disposed above the drift layer; an impurity region of the first conductivity type disposed in a surface layer portion of the body region within the body region and having an impurity concentration higher than that of the drift layer; a plurality of trench gate structures disposed in a plurality of gate trenches that are arranged in a stripe shape and extend along one direction as a longitudinal direction with a depth reaching the drift layer through the body region from the impurity region, each of the plurality of trench gate structures having a double gate structure in which a shield electrode, an intermediate insulation film and a gate electrode layer are sequentially stacked in a corresponding gate trench via an insulation film; a high-concentration layer of the first or second conductivity type disposed on a side opposite to the body region with respect to the drift layer, and having an impurity concentration higher than that of the drift layer; an interlayer insulation film disposed above the plurality of trench gate structures, the body region, and the impurity region; an upper electrode electrically connected to the body region and the impurity region through a contact hole that is formed in the interlayer insulation film in communication with the body region and the impurity region; a gate wiring connected to the gate electrode layer through a contact hole that is formed in the interlayer insulation film in communication with the gate electrode layer; a shield wiring connected to the shield electrode through a contact hole that is formed in the interlayer insulation film in communication with the shield electrode; and a lower electrode electrically connected to the high-concentration layer, in which the upper electrode, the gate wiring and the shield wiring may be electrically isolated from each other.

### BRIEF DESCRIPTION OF DRAWINGS

Features and advantages of the present disclosure will become more apparent from the following detailed description made with reference to the accompanying drawings, in which:

FIG. 1 is a diagram showing a top face layout of a semiconductor device according to a first embodiment of the present disclosure;

FIG. 2A is a diagram showing a cross-sectional view taken along a line IIA-IIA in FIG. 1;

FIG. 2B is a diagram showing a cross-sectional view taken along a line IIB-IIB in FIG. 1;

FIG. 3 is a diagram showing a cross-sectional view taken along a line III-III in FIG. 1;

FIG. 4 is a diagram showing a simplified top face layout of the semiconductor device shown in FIG. 1, in which conductor portions on a top face side are indicated in a transparent manner;

FIG. 5 is a diagram showing a cross-sectional view of a semiconductor device, taken along a longitudinal direction of a trench gate structure, according to a second embodiment of the present disclosure;

FIG. 6 is a diagram showing a top face layout of the semiconductor device shown in FIG. 5, in which conductor portions on a top face side are indicated in a transparent manner;

FIG. 7 is a diagram showing a simplified top face layout of a semiconductor device according to a modification of the second embodiment, in which conductor portions on a top face side are indicated in a transparent manner;

FIG. 8 is a diagram showing a top face layout of a semiconductor device according to a third embodiment of the present disclosure;

FIG. 9 is a diagram showing a simplified top face layout of the semiconductor device shown in FIG. 8, in which conductor portions on a top face side are indicated in a transparent manner;

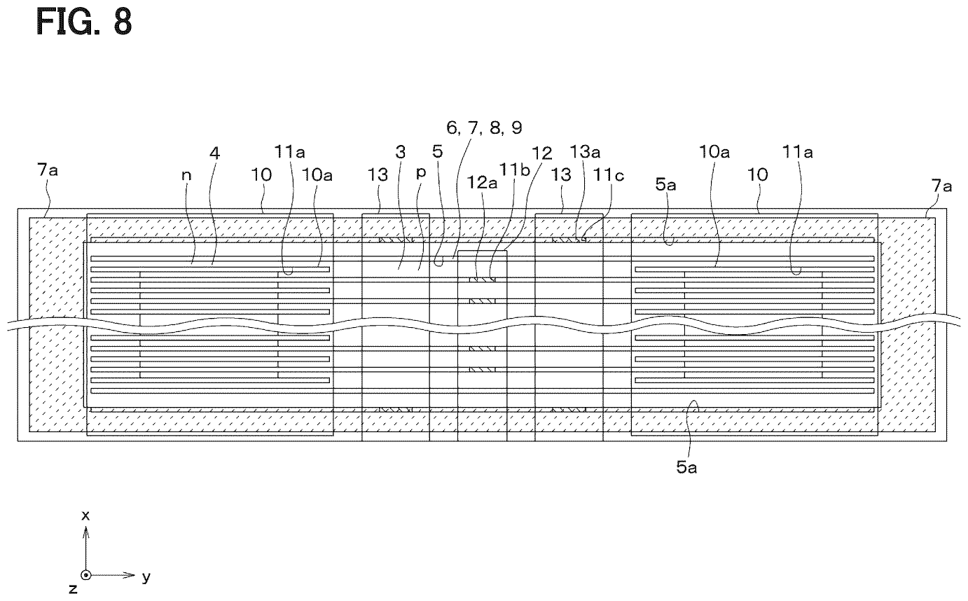

### FIG. 10 is a diagram showing a cross-sectional view taken along a line X-X in FIG. 8;

FIG. 11 is a diagram showing a simplified top face layout of a semiconductor device according to a modification of the third embodiment, in which conductor portions on a top face side are indicated in a transparent manner; and

FIG. 12 is a diagram showing a simplified top face layout of a semiconductor device according to another modification of the third embodiment, in which conductor portions on a top face side are indicated in a transparent manner.

### DETAILED DESCRIPTION

As a related art, there is a semiconductor device including a power MOSFET having a double-gate trench gate structure has been known. The double-gate trench gate structure is formed in a surface layer of a semiconductor substrate in which an n⁻ type drift layer is formed on an n⁺ type substrate. In the double-gate trench gate structure, a shield electrode is disposed at a bottom side of the gate trench via a shield insulation film. Further, a gate electrode layer is disposed above the shield electrode through a gate insulation film in the trench, thereby forming a double gate. An interlayer insulation film, in other words, an intermediate insulation film is formed between the shield electrode and the gate electrode layer. Thus, the intermediate insulation film insulates the shield electrode and the gate electrode layer from each other.

The semiconductor device is designed so that the shield electrode has a source potential, that is, has the same potential as an upper electrode corresponding to a source electrode and a source region, and has a product layout in which a shield wiring connected to the shield electrode is directly connected to the upper electrode. In such a structure, however, it has been found that, when a screening for ensuring reliability is performed on an insulation film of each of parts included in the double-gate trench gate structure, it is sometimes difficult to accurately inspect each insulation film by applying the voltage to the insulation film.

Although a power MOSFET has been indicated as an example of the semiconductor switching element having the double-gate trench gate structure, an IGBT also has similar issues. MOSFET is an abbreviation for a metal oxide semiconductor field effect transistor. IGBT is an abbreviation for an insulated gate bipolar transistor.

The present disclosure provides a semiconductor device including a semiconductor switching element with a double-gate trench gate structure, which enables accurate screening of an insulation film of each part included in the double-gate trench gate structure.

According to an aspect of the present disclosure, a semiconductor device includes a semiconductor switching element with a double-gate trench gate structure. The semiconductor switching element of the semiconductor device includes: a drift layer of a first conductivity type; a body region of a second conductivity type disposed above the drift layer; an impurity region of the first conductivity type disposed in a surface layer portion of the body region within the body region and having an impurity concentration higher than that of the drift layer; a plurality of trench gate structures disposed in a plurality of gate trenches that are arranged in a stripe shape and extend along one direction as a longitudinal direction with a depth reaching the drift layer through the body region from the impurity region, each of the plurality of trench gate structures having a double gate structure in which a shield electrode, an intermediate insulation film and a gate electrode layer are sequentially stacked in a corresponding gate trench via an insulation film; a high-concentration layer of the first or second conductivity type disposed on a side opposite to the body region with respect to the drift layer, and having an impurity concentration higher than that of the drift layer; an interlayer insulation film disposed above the plurality of trench gate structures, the body region, and the impurity region; an upper electrode electrically connected to the body region and the impurity region through a contact hole that is formed in the interlayer insulation film to be connected to the body region and the impurity region; a gate wiring connected to the gate electrode layer through a contact hole that is formed in the interlayer insulation film to be connected to the gate electrode layer; a shield wiring connected to the shield electrode through a contact hole that is formed in the interlayer insulation film to be connected to the shield electrode; and a lower electrode electrically connected to the high-concentration layer, in which the upper electrode, the gate wiring and the shield wiring are electrically isolated from each other.

In a state where semiconductor device is not incorporated in a circuit, the upper electrode, the gate wiring and the shield wiring are electrically isolated from each other. That is, the semiconductor device has a structure in which the upper electrode, the gate electrode layer and the shield electrode are electrically isolated from each other. As such, it is possible to individually control the potentials of the upper electrode, the shield electrode and the gate electrode layer. In this configuration, therefore, it is possible to apply a desired voltage to a position to be inspected when the insulation film or the intermediate insulation film disposed in the gate trench is subjected to screening.

Embodiments of the present disclosure will be described hereinafter with reference to the drawings. In the following, the same or equivalent components will be described with the same reference numerals throughout the embodiments including modifications thereof.

### First Embodiment

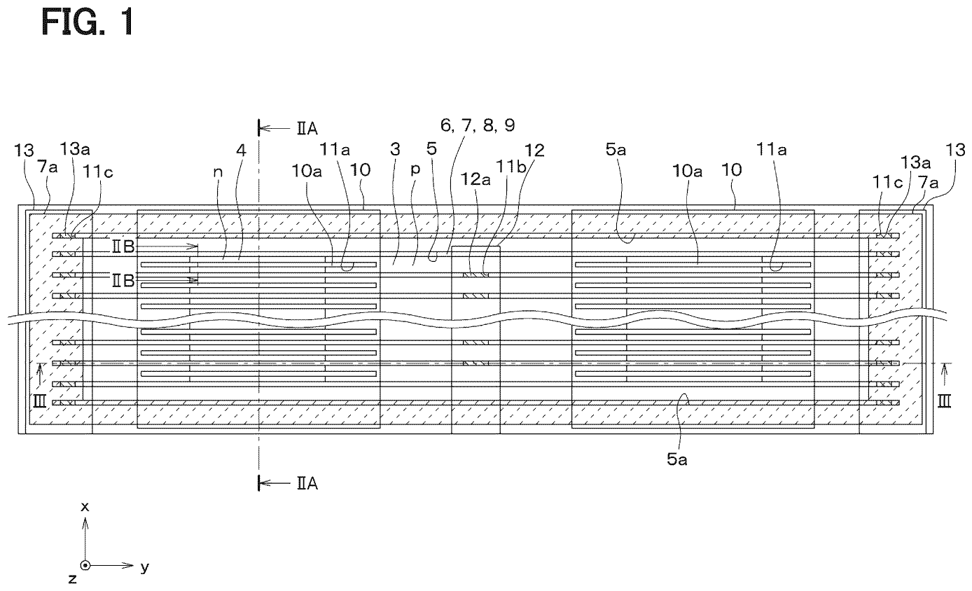

A first embodiment will be described. In the present embodiment, a semiconductor device including an n-channel vertical power MOSFET having a double-gate trench gate structure will be described as an example. MOSFET is an abbreviation for a metal oxide semiconductor field effect transistor. Hereinafter, the n-channel vertical power MOSFET having the double-gate trench gate structure will be simply referred to as the MOSFET. A structure of the semiconductor device according to the present embodiment will be hereinafter described with reference to FIGS. 1 to 4.

In the following, as shown in FIGS. 1 to 3, the description will be given such that a width direction of the MOSFET is referred to as an x direction, a length direction of the MOSFET intersecting with the x direction is referred to as a y direction, and a thickness direction or a depth direction of the MOSFET, that is, the normal direction to the XY plane is referred to as a z direction. In FIG. 1, a first pad portion 10b, which will be described later, is not shown for the sake of clarity.

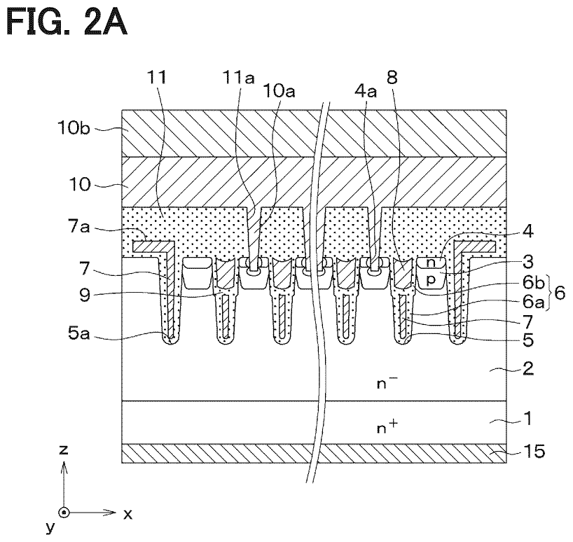

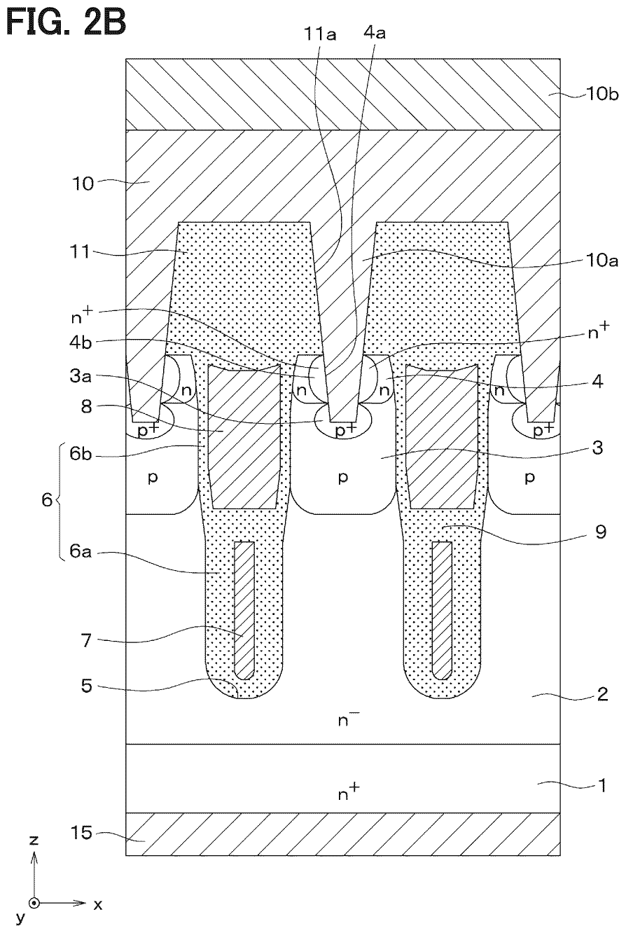

As shown in FIGS. 2A and 2B, the semiconductor device according to the present embodiment is formed by using an n⁺ type semiconductor substrate 1 made of a semiconductor material such as silicon with a high impurity concentration. On the surface of the n⁺ type semiconductor substrate 1, an n⁻ type drift layer 2 having an impurity concentration lower than that of the n⁺ type semiconductor substrate 1 is disposed.

Further, a p type body region 3 having a relatively low impurity concentration is disposed at a certain position in the surface layer portion of the n⁻ type drift layer 2. The p type body region 3 is formed by, for example, ion-implantation of a p type impurity into the n⁻ type drift layer 2. The p type body region 3 also functions as a channel layer for forming a channel region. As shown in FIG. 1, the p type body region 3 is disposed to extend in the y direction as the longitudinal direction between a plurality of trench gate structures, which will be described later.

An n type impurity region 4 is disposed in a surface layer portion of the p type body region 3. The n type impurity region 4 corresponds to a source region, and has an impurity concentration higher than that of the n⁻ type drift layer 2. A contact trench 4a is formed in the n type impurity region 4, so that the p type body region 3 is exposed at the bottom surface of the contact trench 4a. A p⁺type contact region 3a, which serves as a body contact, is disposed in the exposed portion of the p type body region 3. An n⁺ type contact region 4b, which serves as a source contact, is disposed on the side surface of the contact trench 4a in the n type impurity region 4.

A plurality of gate trenches 5 are formed to extend in one direction, i.e., in the y direction, as a longitudinal direction, in the surface layer portion of the n⁻ type drift layer 2 and between the p type body regions 3 and the n type impurity regions 4. The gate trench 5 is a trench for forming the trench gate structure. In the present embodiment, the gate trenches 5 are arranged in parallel at equal intervals so as to have a striped layout.

The gate trench 5 is deeper than the p type body region 3. That is, the gate trench 5 has a depth so that it passes through the n type impurity region 4 and the p type body region 3 from the substrate surface side and reaches the n⁻ type drift layer 2. In the present embodiment, the width of the gate trench 5 gradually narrows toward the bottom, and the gate trench 5 has a rounded bottom end.

The inner wall surface of the gate trench 5 is covered with an insulation film 6. The insulation film 6 may be a single film. In the case of the present embodiment, the insulation film 6 includes a shield insulation film 6a covering the lower portion of the gate trench 5 and a gate insulation film 6b covering the upper portion of the gate trench 5. The shield insulation film 6a covers the side surface of the lower portion from the bottom of the gate trench 5, and the gate insulation film 6b covers the side surface of the upper portion of the gate trench 5. In the present embodiment, the shield insulation film 6a is formed thicker than the gate insulation film 6b.

In addition, inside the gate trench 5, a shield electrode 7 and a gate electrode layer 8 are stacked through the insulation film 6, so that a double gate is formed. The shield electrode 7 and the gate electrode layer are made of doped poly-Si.

The shield electrode 7 is fixed to a source potential in order to reduce a capacitance between a gate and a drain and improve the electrical properties of the MOSFET. The shield electrode 7 allows the part between the trench gate structures to be two-dimensionally depleted. Therefore, it is possible to achieve a desired breakdown voltage even if the thickness of the n⁻ type drift layer 2 is thin, as compared to a MOSFET with a single gate structure. In addition, since the n⁻ type drift layer 2 can be made thin, it is possible to achieve a low on-resistance. However, in the semiconductor device of the present embodiment, the shield electrode 7 is isolated from the source, so that a voltage different from the source can be applied to the shield electrode 7. The structure of the shield electrode 7 will be described in detail later.

The gate electrode layer 8 is to perform a switching operation of the MOSFET, and causes a channel region in the p type body region 3 on the side surface of the gate trench 5 when a gate voltage is applied.

An intermediate insulation film 9 is disposed between the shield electrode 7 and the gate electrode layer 8. The shield electrode 7 and the gate electrode layer 8 are insulated by the intermediate insulation film 9. The gate trench 5, the insulation film 6, the shield electrode 7, the gate electrode layer 8, and the intermediate insulation film 9 form the trench gate structure. The trench gate structure extends in the y direction, i.e., in the horizontal direction in FIG. 1, as the longitudinal direction. The multiple trench gate structures are arranged in the x direction, i.e., in the vertical direction in FIG. 1 and in the horizontal direction in FIGS. 2A and 2B, thereby to form the striped layout. The n type impurity region 4 and the like are formed in a region further inside than both the ends in the longitudinal direction of the trench gate structures, and this region forms a cell part that functions as the MOSFET. Regions at both the ends of the trench gate structure in the longitudinal direction, which are outside of the cell part, are included in an outer peripheral part.

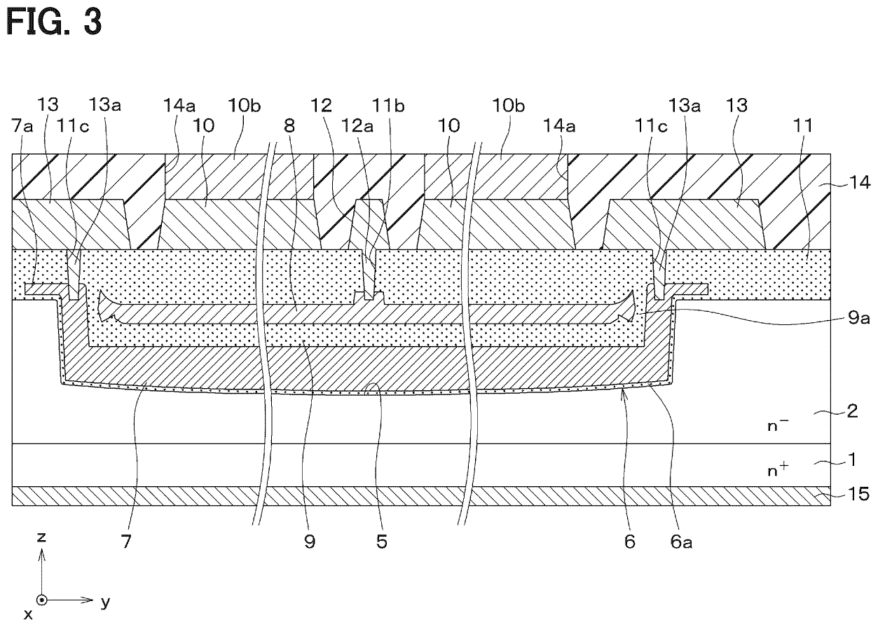

As shown in FIG. 3, at both ends of the gate trench 5 in the longitudinal direction, that is, in the outer peripheral part, the shield electrode 7 is extended outside beyond the gate electrode layer 8. The portions of the shield electrode 7 protruded outside of the gate trench 5 are exposed from the surface side of the p type body region 3 and the n type impurity region 4, to serve as a shield liner 7a. The shield liner 7a is disposed not only at both longitudinal ends of the gate trenches 5 but also along the gate trenches 5 at both ends among the multiple gate trenches 5 in the x direction so as to sandwich the gate trenches 5 in the x direction, as shown in FIG. 1. Although FIG. 1 is not a cross-sectional view, the shield liner 7a is shown by dashed hatching for the sake of clarity. Among the multiple gate trenches 5 arranged in the x direction, the gate trenches 5 disposed at the outermost positions will be referred to as the end trenches 5a. In this case, as shown in FIG. 2A, the end trenches 5a are filled with the shield electrode 7 and no gate electrode layer 8 is disposed in the end trenches 5a. The shield electrode 7 filling the end trench 5a is extended to protrude outside of the end trench 5a toward external region of the multiple gate trenches 5, so that this protruded portion also serves as the shield liner 7a. That is, the shield liner 7a has the layout so as to surround the cell part.

At each end of each of the multiple gate trenches 5 in the longitudinal direction, a tip portion 9a of the intermediate insulation film 9 is disposed between the portion of the shield electrode 7 that extends outward from the gate electrode layer 8 and the end of the gate electrode layer 8. By the tip portions 9a, the shield electrode 7 and the gate electrode layer 8 are insulated from each other also at both longitudinal ends of the gate trench 5.

An interlayer insulation film 11 made of an oxide film or the like is formed so as to cover the gate electrode layer 8. Further, an upper electrode 10, a gate wiring 12 and a shield wiring 13 are formed above the interlayer insulation film 11. The upper electrode 10 corresponds to a source electrode. As shown in FIGS. 2A and 2B, the upper electrode 10 is in contact with the p type body region 3 and the n type impurity region 4 through a connection portion 10a, such as a tungsten (W) plug, embedded in a contact hole 11a formed in the interlayer insulation film 11. As a result, the upper electrode 10 is electrically connected to the n type impurity region 4 and the p type body region 3.

As shown in FIG. 3, the gate wiring 12 is electrically connected to the gate electrode layer 8 through a connection portion 12a, such as a tungsten (W) plug, disposed in a contact hole 11b formed in the interlayer insulation film 11. Likewise, the shield wiring 13 is electrically connected to the shield electrode 7 through a connection portion 13a, such as a W plug, disposed in a contact hole 11b formed in the interlayer insulation film 11. As described above, the shield liner 7a is formed so as to surround the cell part in which the multiple trench gate structures are formed and which operates as the MOSFET. In the case of the present embodiment, the shield wirings 13 are disposed on the portions of the shield liner 7a that are located at both ends of the trench gate structures. The shield wirings 13 are not provided on the portions of the shield liner 7a that extend along the longitudinal direction of the trench gate structures. With this structure, the upper electrode 10 and the shield wiring 13 are electrically isolated from each other.

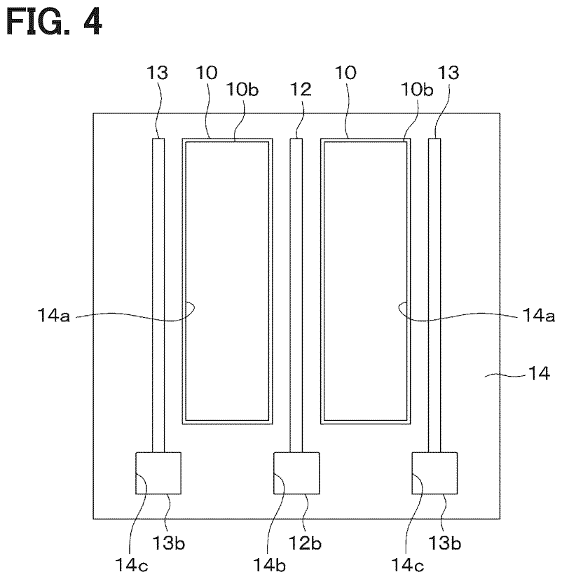

Further, as shown in FIG. 3, a protective film 14 is disposed so as to cover the upper electrode 10, the gate wiring 12, the shield wiring 13 and the interlayer insulation film 11. The upper electrode 10, the gate wiring 12, and the shield wiring 13 are electrically isolated from each other through the protective film 14. FIG. 4 shows this structure in a simplified manner. That is, the gate wiring 12 is extended between two upper electrodes 10, and one shield wiring 13 is extended on each of the opposite sides of the two upper electrodes 10 and the gate wiring 12 in the outer peripheral part. The two upper electrodes 10 are separated from each other and each have a rectangular shape. The two upper electrode 10 may also be referred to as a first upper electrode portion and a second upper electrode portion. The gate wiring 12 and the shield wirings 13 are extended along the x direction. One end of each of the gate wiring 12 and the shield wirings 13 is extended outward beyond the upper electrode 10 in the x direction. The one end of the gate wiring 12 extended beyond the upper electrode 10 is connected to a second pad portion 12b, and the one end of the shield wiring 13 extended beyond the upper electrode 10 is connected to a third pad portion 13b. As shown in FIG. 3, the upper electrode 10 is connected to a first pad portion 10b. The first pad portion 10b is connected to almost the entire surface of the upper electrode 10, and has a rectangular shape similar to the upper electrode 10 as shown in FIG. 4.

As shown in FIGS. 3 and 4, the first pad portion 10b is electrically connected to the upper electrode 10 through a first opening 14a formed in the protective film 14. As shown in FIG. 4, the second pad portion 12b is disposed in a second opening 14b formed in the protective film 14. The second pad portion 12b is electrically connected to the gate wiring 12. Similarly, the third pad portion 13b is disposed in a third opening 14c formed in the protective film 14. The third pad portion 13b is electrically connected to the shield wiring 13. The upper electrode 10, the gate wiring 12 and the shield wirings 13 are insulated from each other by the protective film 14. Further, the first pad portions 10b, the second pad portion 12b and the third pad portions 13b are also disposed at positions physically separated from each other. Therefore, these are electrically isolated from each other. In other words, the shield electrode 7 is separated from the source, so that a voltage different from that of the source can be applied to the shield electrode 7.

The semiconductor device of the present embodiment is incorporated, for example, in an inverter circuit when in use. In such a case, the first pad portions 10b, the second pad portion 12b, and the third pad portions 13b are electrically connected to parts external of the semiconductor device. In such a case, although not shown, the first pad portion 10b and the third pad portion 13b are bonded to the same conductive block via a bonding material such as solder, thereby being electrically connected. Therefore, in the semiconductor device of the present embodiment, the shield electrode 7 is isolated from the source so that a voltage different from that of the source can be applied. In addition, when this semiconductor device is incorporated into a circuit, the shield electrode 7 is fixed to the source potential.

On the other hand, a lower electrode 15 is disposed on the surface of the n⁺ type semiconductor substrate 1 on a side opposite to the n⁻ type drift layer 2. The lower electrode 15 corresponds to a drain electrode. This configuration constitutes the basic structure of the MOSFET. The cell part is constituted by a plurality of MOSFET cells, and thus the semiconductor device of the present embodiment including the MOSFET with the double-gate trench gate structure is constituted.

The method for manufacturing the semiconductor device of the present embodiment is basically similar to the method for manufacturing a conventional semiconductor device including a power MOSFET with a double-gate trench gate structure. However, the semiconductor device of the present embodiment is designed to have the top face layout in which the upper electrodes 10 and the shield wirings 13 are electrically isolated from each other, as well as the first pad portions 10b and the third pad portions 13b are electrically isolated from each other.

As described above, in the state where the semiconductor device is not incorporated into a circuit, the upper electrode 10, the gate wiring 12 and the shield wiring 13 are electrically isolated from each other. In other words, the upper electrode 10, the shield electrode 7 and the gate electrode layer 8 are electrically isolated from each other.

For this reason, the potentials of the upper electrode 10, the shield electrode 7 and the gate electrode layer 8 can be controlled individually. Therefore, when the insulation film 6 and the intermediate insulation film 9, which are disposed in the gate trench 5, are subjected to screening, it is possible to apply a desired voltage to the position to be inspected.

For example, the shield insulation film 6a, the gate insulation film 6b, and the intermediate insulation film 9, are three target positions for screening.

The shield insulation film 6a is subjected to the screening to check whether the thickness of the shield insulation film 6a, particularly, the thickness of the portion located at the bottom of the gate trench 5 satisfies a designed breakdown voltage. In this case, a desired voltage is applied to the lower electrode 15 as well as a desired voltage, for example, a ground potential is applied to the shield electrode 7 via the third pad portion 13b. By generating a potential difference between the shield electrode 7 and the lower electrode 15, a high electric field is applied to the shield insulation film 6a. This allows for the inspection of the shield insulation film 6a for any scratches or foreign matter contamination.

The gate insulation film 6b is also subjected to the screening to check whether the thickness of the gate insulation film 6b satisfies a designed breakdown voltage. In this case, a desired voltage is applied to the gate electrode layer 8 via the second pad portion 12b as well as a desired voltage, for example, a ground potential is applied to the upper electrode 10 via the first pad portion 10b. By generating a potential difference between the gate electrode layer 8 and the n type impurity region 4, an electric field is applied to the gate insulation film 6b. This allows for the inspection of the gate insulation film 6b for any scratches or foreign matter contamination.

Furthermore, the intermediate insulation film 9 is also subjected to the screening to check whether the thickness of the intermediate insulation film 9 satisfies a designed breakdown voltage. In this case, a desired voltage is applied to the gate electrode layer 8 via the second pad portion 12b as well as a desired voltage, for example, a ground potential is applied to the shield electrode 7 via the third pad portion 13b. By generating a potential difference between the gate electrode layer 8 and the shield electrode 7, an electric field is applied to the intermediate insulation film 9. This allows for the inspection of the intermediate insulation film 9 for any scratches or foreign matter contamination.

In this way, different voltages can be applied to the shield electrode 7, the gate electrode layer 8, and the upper electrode 10, respectively. As such, the screening of each of the shield insulation film 6a, the gate insulation film 6b, and the intermediate insulation film 9 can be performed accurately.

For example, when the gate insulation film 6b is subjected to the screening, if the shield electrode 7 and the upper electrode 10 are electrically connected and have the same potential, the screening may not be performed accurately. When the gate insulation film 6b is subjected to the screening, a potential difference is generated between the n type impurity region 4 or the upper electrode 10 and the gate electrode layer 8. In this case, if the upper electrode 10 and the shield electrode 7 have the same potential, the same potential difference is also generated between the gate electrode layer 8 and the shield electrode 7. Therefore, if the intermediate insulation film 9 is damaged or contaminated with foreign matter, the thickness of the intermediate insulation film 9 at that portion becomes thinner than the thickness of the gate insulation film 6b, and the thinner portion is screened. As a result, it difficult to perform the screening accurately.

On the other hand, in the semiconductor device of the present embodiment, the shield electrode 7 and the upper electrode 10 are electrically isolated from each other and can have different potentials. Therefore, when the gate insulation film 6b is subjected to the screening, the electric field can be applied precisely only to the gate insulation film 6b. For example, by generating the potential difference between the n type impurity region 4 or the upper electrode 10 and the gate electrode layer 8 while controlling the gate electrode layer 8 and the shield electrode 7 to have the same potential, the electric field can be applied to the gate insulation film 6b, but no electric field is applied to the intermediate insulation film 9.

Therefore, in the semiconductor device including the semiconductor switching element having the double-gate trench gate structure, it is possible to accurately perform the screening for the insulation film 6 and the intermediate insulation film 9 included in the trench gate structure.

In the semiconductor device of the present embodiment, the gate wiring 12 is disposed at the center position in the longitudinal direction of the trench gate structure. That is, the semiconductor device of the present embodiment does not have a structure in which the gate wiring 12 is connected to the gate electrode layer 8 only at one end in the longitudinal direction of the trench gate structure. Therefore, as compared to such a structure, the semiconductor device of the present embodiment can shorten the distance from the gate wiring 12 to the gate electrode layer 8 at both ends in the longitudinal direction of the trench gate structure. As such, when the gate voltage is applied to the gate electrode layer 8 during switching of the MOSFET, it is possible to suppress the occurrence of a time delay before the gate voltage is applied to the gate electrode layer 8 at both ends in the longitudinal direction of the trench gate structure.

### Second Embodiment

A second embodiment will be described. In the present embodiment, the layout of the shield wirings 13 and the like is changed from that of the first embodiment. The other configurations of the present embodiment are similar to those of the first embodiment, so only the parts that are different from the first embodiment will be described hereinafter.

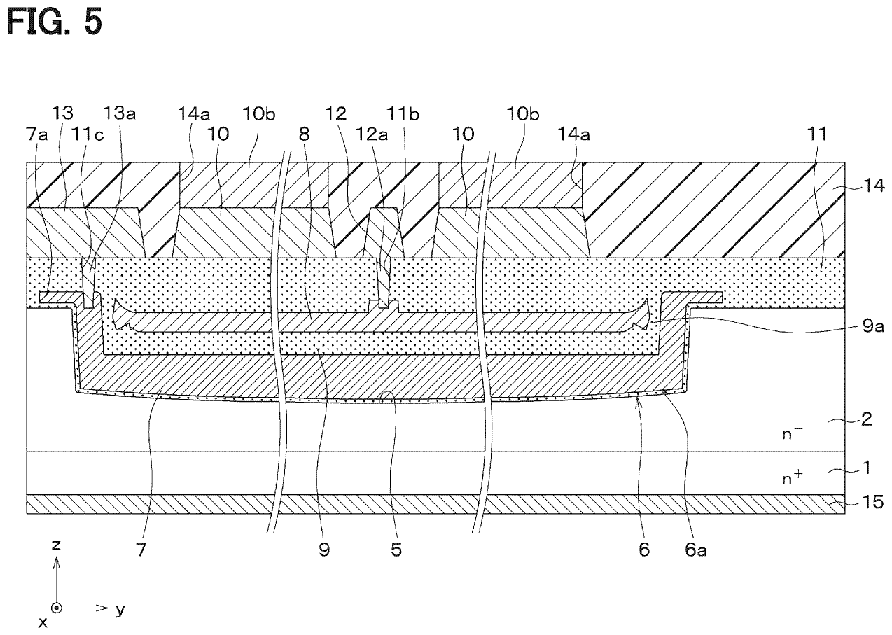

As shown in FIG. 5, in the semiconductor device of the present embodiment, the shield wiring 13, which is connected to the shield liner 7a via the connection portion 13a, is provided only at one end of the trench gate structure in the longitudinal direction, i.e., the left end side in FIG. 5. The shield wiring 13 and the connection portion 13a are not provided at the other end of the trench gate structure in the longitudinal direction, i.e., the right end side in FIG. 5.

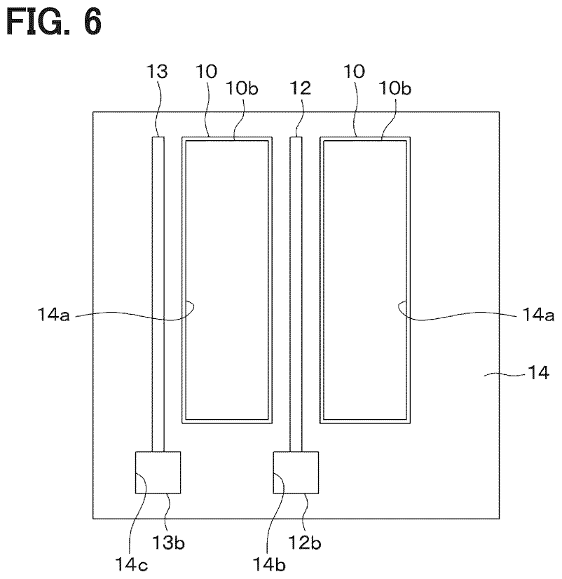

In such a structure, as shown in FIG. 6, the gate wiring 12 is extended between the two upper electrodes 10, which are separated from each other and have the rectangular shape. Further, one shield wiring 13 is extended in the outer peripheral part and on the opposite side to the gate wiring 12 with respect to one of the upper electrodes 10 interposed therebetween. The shield wiring 13 is extended along the x direction, so that one end of the shield wiring 13 is located outside beyond the upper electrode 10 in the x direction and is connected to the third pad portion 13b.

As described above, the semiconductor device can have a structure in which the gate wiring 12 and the second pad portion 12b are arranged on one side of one upper electrode 10, and the shield wiring 13 and the third pad portion 13b are arranged on the other side of the one upper electrode 10. Also in such a structure, the similar effects to those in the first embodiment can be achieved.

### Modification of Second Embodiment

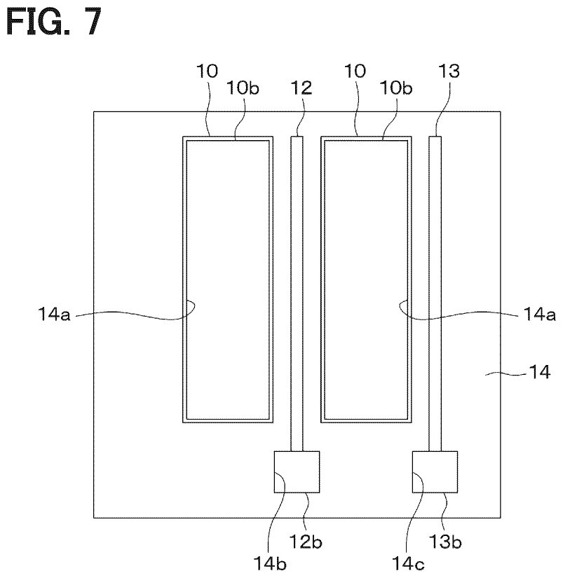

In the second embodiment described above, when the semiconductor device is viewed from above as shown in FIGS. 5 and 6, the shield wiring 13 and the third pad portion 13b are arranged on the left side of the upper electrode 10, and the shield electrode 7 is connected to the shield wiring 13 and the third pad portion 13b via the connection portion 13a. As another example, as shown in FIG. 7, the shield wiring 13 and the third pad portion 13b may be arranged on the right side of the upper electrode 10 when the semiconductor device is viewed from above, and the shield electrode 7 may be connected to the shield wiring 13 and the third pad portion 13b via the connection portion 13a.

In this case, “when the semiconductor device is viewed from above” refers to a state when the semiconductor device is viewed so that the second pad portion 12b arranged outside the upper electrode 10 is shown below the upper electrode 10.

### Third Embodiment

A third embodiment will be described. In the present embodiment, the layout of the shield wiring 13 and the like is changed from that of the first embodiment. The other configurations are similar to those of the first embodiment, so only the parts that are different from the first embodiment will be described.

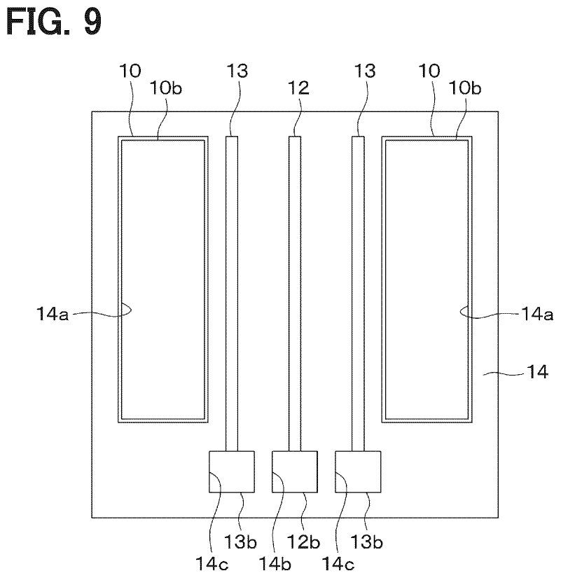

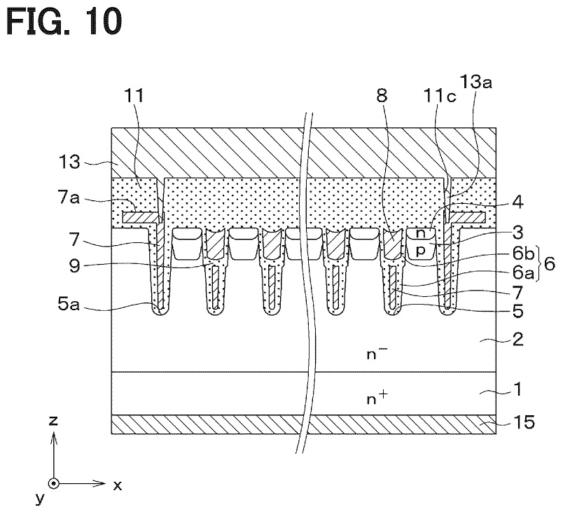

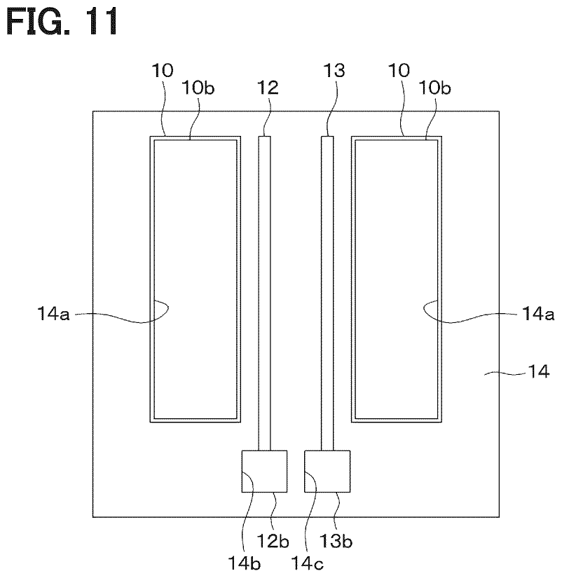

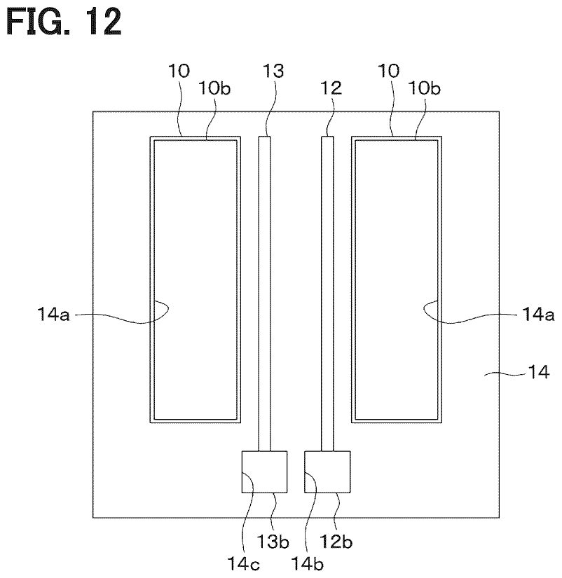

As shown in FIGS. 8 and 9, in the present embodiment, not only the gate wiring 12 but also the shield wirings 13 are extended between the two upper electrodes 10, which are separated from each other and have the rectangular shape. The shield wirings 13 are arranged on opposite sides of the gate wiring 12. Thus, the two shield wirings 13 and one gate wiring 12 are disposed between the two upper electrodes 10.

As shown by the dashed hatching in FIG. 8, the shield liner 7a is formed so as to surround the cell part. The shield wiring 13 is arranged so as to intersect with each of the trench gate structures, for example, at the vicinity of the center position of the cell part, and is arranged to overlap the portion of the shield liner 7a that extends along the end trench 5a. In this portion, as shown in FIGS. 8 and 10, the shield wiring 13 and the shield liner 7a are connected via the connection portion 13a. On the other hand, although the upper electrode 10 and the gate wiring 12 are arranged to partially overlap with the portion of the shield liner 7a that extends along the end trench 5a, the upper electrode 10 and the gate wiring 12 are isolated by the interlayer insulation film 11 shown in FIG. 2A and the like, and are not connected to each other.

As described above, the semiconductor device can have a structure in which one gate wiring 12 and two shield wirings 13 are arranged so as to be located between the two upper electrodes 10. Also in such a structure, the similar effects to those in the first embodiment can be achieved.

### Modifications of Third Embodiment

In the third embodiment described above, one shield wiring 13 is provided between the gate wiring 12 and one of the two upper electrodes 10, and another shield wiring 13 is provided between the gate wiring 12 and the other of the two upper electrodes 10. That is, the gate wiring 12 is interposed between the two shield wirings 13. Alternatively, only one shield wiring 13 may be provided between the two upper electrodes 10. Specifically, as shown in FIGS. 11 and 12, one shield wiring 13 may arranged along the gate wiring 12, and this shield wiring 13 and this gate wiring 12 may be interposed between the two separated upper electrodes 10. In such a case, when the semiconductor device is viewed from above, one single shield wiring 13 and one third pad portion 13b may be disposed on the right side of the gate wiring 12 and the second pad portion 12b as shown in FIG. 11, or may be disposed on the left side as shown in FIG. 12.

### Other Embodiments

While the present disclosure has been described in accordance with the embodiments described above, the present disclosure is not limited to the embodiments and includes various modifications and equivalent modifications. In addition, as the various combinations and configurations, which are preferred, other combinations and configurations, including more, less or only a single element, are also within the spirit and scope of the present disclosure.
(1) For example, in the embodiment(s) described above, the high-concentration layer, which is a high-concentration n type impurity layer, is made of the semiconductor substrate 1, and the n⁻ type drift layer 2 is epitaxially grown on top of the high-concentration layer, thereby forming the substrate including the high-concentration layer and the n⁻ type drift layer 2. This is merely an example of a case where the high-concentration layer is formed opposite to the p type body region 3 with respect to the n⁻ type drift layer 2. As another example, the n⁻ type drift layer 2 may be made of the semiconductor substrate, and the high-concentration layer may be formed on one surface thereof by ion implantation or the like.
(2) In the embodiment(s) described above, the p type body regions 3 arranged between the plurality of trench gate structures are formed along the y direction, and the n type impurity regions 4 are also formed along the y direction. However, this is merely an example. As another example, the n type impurity region 4 may be divided into a plurality of portions in the y direction as a broken-line shape. That is, it is sufficient that the n type impurity region 4 is formed in a part of the surface of the p type body region 3.
(3) Further, in the embodiment(s) described above, the p⁺ type contact region 3a is formed at the center position in the x direction in the p type body region 3, and the n⁺ type contact region 4b is formed at the center position in the x direction in the n type impurity region 4. However, this is described as a preferred embodiment, and it does not matter if the arrangement position thereof is shifted due to the influence of mask misalignment or the like, or if these are not formed at all.
(4) In the embodiment(s) described above, the second pad portion 12b and the third pad portion 13b are disposed outside of the upper electrode 10 and the first pad portion 10b in the x direction and in the same direction. That is, when the semiconductor device is viewed from above, the second pad portion 12b and the third pad portion 13b are both disposed below the upper electrode 10 and the first pad portion 10b. In other words, the second pad portion 12b and the third pad portion 13b are disposed on the outer side of the upper electrode 10 and the first pad portion 10b, in one direction along the x direction, which intersects with the plurality of gate trenches. However, this is merely an example. As another example, the third pad portion 13b and the second pad portion 12b may be disposed outside and on opposite sides of the upper electrode 10 in the x direction.

In the embodiment described above, for example, only the first pad portion 10b connected to the upper electrode 10, the second pad portion 12b connected to the gate wiring 12, and the third pad portion 13b connected to the shield wiring 13 are shown. However, the semiconductor device may have a structure including a temperature sensing element. Also, the cell part may be separated into a main cell and a sense cell, and a current flowing through the sense cell side may be sensed. In such a case, other pads, such as a pad connected to the temperature sensing element and a pad for sensing the current in the sense cell, may be arranged. These pads may be connected to the outside of the semiconductor device via bonding wires or lead frames. However, it is not always necessary that all of these pads are connected in the same manner. For example, the second pad portion 12b may be electrically connected to the outside of the semiconductor device via a bonding wire, and the first pad portion 10b and the third pad portion 13b may be electrically connected to the outside of the semiconductor device via a conductive block. In this case, if the second pad portion 12b on which wire bonding is performed is positioned on the side opposite to the third pad portion 13b bonded to the conductive block, the first pad portion 10b and the third pad portion 13b can be bonded to the conductive block without considering the second pad portion 12b. Therefore, it is possible to simplify the shape of the conductive block. For example, the conductive block may have a simply rectangular parallelepiped shape.
(5) In the embodiment(s) described above, the MOSFET of the n-channel type trench gate structure in which the first conductivity type is the n type and the second conductivity type is the p type has been illustrated as an example of the semiconductor switching element. However, this is merely an example, and a semiconductor switching element of another structure, for example, a MOSFET of a p-channel type trench gate structure in which the conductivity type of each component is inverted with respect to the n-channel type may be employed. The present disclosure can be applied to an insulated gate bipolar transistor (IGBT) having a similar construction, in addition to the MOSFET. In the case of the IGBT, the conductivity type of the semiconductor substrate 1 is changed from the n type to the p type, and the other configurations are the same as those of the MOSFET of the embodiment(s) described above.

What is claimed is:

1. A semiconductor device comprising:
a semiconductor switching element that includes:
a drift layer of a first conductivity type;
a body region of a second conductivity type disposed above the drift layer;
an impurity region of the first conductivity type disposed in a surface layer portion of the body region within the body region and having an impurity concentration higher than that of the drift layer;
a plurality of trench gate structures disposed in a plurality of gate trenches that are arranged in a stripe shape and extend along one direction as a longitudinal direction with a depth reaching the drift layer through the body region from the impurity region, each of the plurality of trench gate structures having a double gate structure in which a shield electrode, an intermediate insulation film and a gate electrode layer are sequentially stacked in a corresponding gate trench via an insulation film;
a high-concentration layer of the first or second conductivity type disposed on a side opposite to the body region with respect to the drift layer, and having an impurity concentration higher than that of the drift layer;
an interlayer insulation film disposed above the plurality of trench gate structures, the body region, and the impurity region;
an upper electrode electrically connected to the body region and the impurity region through a contact hole that is formed in the interlayer insulation film to be connected to the body region and the impurity region;
a gate wiring connected to the gate electrode layer through a contact hole that is formed in the interlayer insulation film to be connected to the gate electrode layer;
a shield wiring connected to the shield electrode through a contact hole that is formed in the interlayer insulation film to be connected to the shield electrode; and
a lower electrode electrically connected to the high-concentration layer, wherein
the upper electrode, the gate wiring and the shield wiring are electrically isolated from each other,
a part including both ends in the longitudinal direction of the plurality of gate trenches is referred to as an outer peripheral part,
a part inside of the outer peripheral part is referred to as a cell part,
in the cell part, the body region and the impurity region are disposed to constitute the semiconductor switching element,
the plurality of gate trenches includes an end trench disposed at an outermost end and in which the shield electrode is embedded without the gate electrode layer,
the shield electrode includes, in the outer peripheral part, a shield liner that has a portion extending outward beyond the gate electrode layer and protruding outward beyond the plurality of gate trenches in the longitudinal direction of the plurality of gate trenches, and a portion protruding outward beyond the end trench in a direction intersecting with the longitudinal direction of the plurality of gate trenches and extending along the longitudinal direction of the plurality of gate trenches,
the gate wiring is disposed at a center position in the longitudinal direction of the plurality of gate trenches, and extends in the direction intersecting with the longitudinal direction of the plurality of gate trenches,
the upper electrode includes a first upper electrode portion and a second upper electrode portion that are disposed on opposite sides of the gate wiring, and
the shield wiring is disposed in at least one of a first position between the first upper electrode portion and the gate wiring or a second position between the second upper electrode portion and the gate wiring, and extends in the direction intersecting with the longitudinal direction of the plurality of gate trenches.

2. The semiconductor device according to claim 1, further comprising:
a protective film disposed above the upper electrode, the gate wiring, and the shield wiring, in addition to the interlayer insulation film;
a first pad portion electrically connected to each of the first and second upper electrode portions through a first opening that is formed in the protective film;
a second pad portion electrically connected to the gate wiring through a second opening that is formed in the protective film; and
a third pad portion electrically connected to the shield wiring through a third opening portion that is formed in the protective film, wherein
the first pad portion, the second pad portion and the third pad portion are electrically isolated from each other.

3. The semiconductor device according to claim 2, wherein
the second pad portion is disposed outside of the first pad portion in the direction intersecting with the longitudinal direction of the plurality of gate trenches, and
the third pad portion is disposed outside of the first pad portion in the direction intersecting with the longitudinal direction of the plurality of gate trenches.

4. The semiconductor device according to claim 2, wherein
the second pad portion is disposed outside of the first pad portion in the direction intersecting with the longitudinal direction of the plurality of gate trenches, and
the third pad portion is disposed outside of the first pad portion on a side opposite to the second pad portion in the direction intersecting with the longitudinal direction of the plurality of gate trenches.
